(19) United States
(12) Patent Application Publication
(10) Pub. No.: US 2026/0090427 A1
(43) Pub. Date: Mar. 26, 2026

(54) GLASS CORE SUBSTRATE WITH EDGE BIAS

(71) Applicant: Intel Corporation, Santa Clara, CA (US)

(72) Inventors: Bohan SHAN, Chandler, AZ (US); Wei LI, Chandler, AZ (US); Jose WAIMIN, Gilbert, AZ (US); Ryan CARRAZZONE, Chandler, AZ (US); Kyle ARRINGTON, Gilbert, AZ (US); Ziyin LIN, Chandler, AZ (US); Dingying David XU, Chandler, AZ (US); Hongxia FENG, Chandler, AZ (US); Yiqun BAI, Chandler, AZ (US); Hiroki TANAKA, Gilbert, AZ (US); Brandon C. MARIN, Gilbert, AZ (US); Jeremy D. ECTON, Gilbert, AZ (US); Benjamin DUONG, Phoenix, AZ (US); Gang DUAN, Chandler, AZ (US); Srinivas Venkata Ramanuja PIETAMBARAM, Chandler, AZ (US); Rui ZHANG, Chandler, AZ (US); Mohit GUPTA, Chandler, AZ (US)

(21) Appl. No.: 18/898,431

(22) Filed: Sep. 26, 2024

(51) Int. Cl. H01L 23/13; H01L 23/14

(52) U.S. Cl. CPC H10W 70/68; H10W 70/695

(57) ABSTRACT

Embodiments disclosed herein may include an apparatus that includes a first substrate, where the first substrate comprises a glass layer, and a second substrate over the first substrate, where the second substrate comprises an organic buildup layer. In an embodiment, a first width of the first substrate is greater than a second width of the second substrate. In an embodiment, an edge between a first corner of the first substrate and a second corner of the first substrate comprises a curve.

### BACKGROUND

Advanced packaging solutions are desired as electronic packaging continues to increase in complexity. For example, the interconnection of multiple dies, systems, and/or other components within a single electronic package has driven devices to have smaller features, improved alignment accuracy, and/or the like. Existing package substrates that rely on organic core materials suffer from high warpages, poor flatness, and poor ability to scale to smaller via sizes. One proposed solution is to replace organic core materials with glass cores.

Glass cores provide significant benefits, such as reducing substrate warpage and enabling through core via pitch reductions. However, the singulation and handling of glass core substrates is not without issue. The fragile nature of the glass core materials may provide additional defect and/or failure modes during package substrate fabrication, handling, and/or during deployment in an operating condition. For example, glass cracking, seware damage, and/or the like may result in complete failure of the package substrate.

### BRIEF DESCRIPTION OF THE DRAWINGS

FIG. 1A is a cross-sectional illustration of a package substrate with a glass core that extends past edges of the overlying and underlying buildup layers, in accordance with an embodiment.

FIG. 1B is a cross-sectional illustration of a package substrate with a glass core that is protected by a buffer layer with a curved outer edge, in accordance with an embodiment.

FIG. 2A is a cross-sectional illustration of a package substrate with a glass core that is protected by a buffer layer that is confined by a frame, in accordance with an embodiment.

FIG. 2B is a cross-sectional illustration of a package substrate with a glass core that is protected by a buffer layer that is confined by a frame, in accordance with an additional embodiment.

FIG. 3A-3D are plan view illustrations depicting a process for applying a buffer layer and a frame around a package substrate with a glass core, in accordance with an embodiment.

FIG. 3E is a flow diagram of a process for applying a buffer layer and a frame around a package substrate with a glass core, in accordance with an embodiment.

FIG. 4A is a plan view illustration of a portion of a package substrate with a buffer layer with a curved surface along an edge of the package substrate, in accordance with an embodiment.

FIG. 4B is a plan view illustration of the portion of the package substrate in FIG. 4A during the application of a gas pressing operation against the buffer layer and a curing process, in accordance with an embodiment.

FIG. 4C is a cross-sectional illustration of the package substrate in FIG. 4B with a buffer layer that has a substantially vertical profile, in accordance with an embodiment.

FIG. 4D is a cross-sectional illustration of the package substrate in FIG. 4B with a buffer layer that comprises a bowl-shaped profile, in accordance with an embodiment.

FIG. 4E is a flow diagram of a process for applying a buffer layer with a vertical edge to a package substrate using a gas flow and curing process, in accordance with an embodiment.

FIG. 5A is a plan view illustration of a package substrate with a glass core that includes one or more edges with a curved profile, in accordance with an embodiment.

FIG. 5B is a plan view illustration of the package substrate in FIG. 5A after a buffer layer is applied, where the curved profile of the one or more edges biases the edge profile of the buffer layer so that the edges are substantially planar, in accordance with an embodiment.

FIG. 5C is a plan view illustration of a package substrate with a glass core that includes one or more corners with circular protrusions, in accordance with an embodiment.

FIG. 5D is a plan view illustration of the package substrate in FIG. 5C after a buffer layer is applied, where the circular protrusions at the corners bias the edge profile of the buffer layer so that the edges are substantially planar, in accordance with an embodiment.

FIG. 5E-5H are plan view illustrations of package substrates with glass cores that included edges with bias inducing patterns in order to provide a buffer layer with planar edges, in accordance with various embodiments.

FIG. 5I is a flow diagram of a process for forming a package substrate with a glass core that includes a biased edge for controlling an edge profile of a buffer layer deposited over the edge of the glass core, in accordance with an embodiment.

FIG. 6A-6D are corresponding plan view and cross-sectional view illustrations depicting a process for applying a buffer layer around a package substrate with a glass core using a roller coating process and a scraper, in accordance with an embodiment.

FIG. 7A is a plan view schematic illustration of a system for implementing a process for applying a buffer layer along an edge of a package substrate that comprises a glass layer, in accordance with an embodiment.

FIG. 7B is a flow diagram of a process for applying a buffer layer along an edge of a package substrate that comprises a glass layer, in accordance with an embodiment.

FIG. 8A is a cross-sectional illustration of a portion of a package substrate with a glass core and a vacuum assisted scraper for defining an edge profile of a buffer layer applied over an edge of the package substrate, in accordance with an embodiment.

FIG. 8B is a plan view illustration of a package substrate with a glass core as a vacuum assisted scraper is defining an edge profile of a buffer layer applied to the package substrate, in accordance with an embodiment.

FIG. 8C-8E are cross-sectional illustrations of a portion of package substrates that depict different buffer layer cross-sectional profiles, in accordance with various embodiments.

FIG. 8F is a flow diagram of a process for defining an edge profile of a buffer layer on a package substrate with a glass core, in accordance with an embodiment.

FIG. 9 is a cross-sectional illustration of an electronic system with a package substrate that comprises a buffer layer with a defined cross-sectional profile, in accordance with an embodiment.

FIG. 10 is a schematic of a computing device built in accordance with an embodiment.

### EMBODIMENTS OF THE PRESENT DISCLOSURE

Described herein are a package substrate architecture that comprise a protective layer over an edge of a glass core, in accordance with various embodiments. In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

As noted above, the use of glass cores in package substrates allows for improved performance and further scaling to smaller feature sizes and pitches. For example, the use of a glass core substrate allows for better warpage performance, improved dimensional stability, and improved flatness. However, singulation and handling of the glass core substrates are problematic due to the fragile nature of glass. For example, the glass may be susceptible to cracking, seware damage, and/or the like during processing, during assembly, and/or during operation.

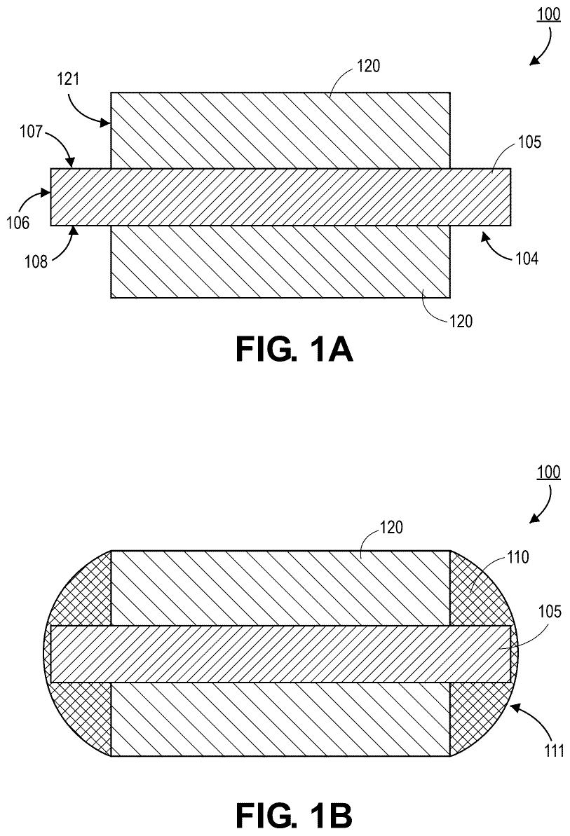

The potential damage to the glass core substrate is made more prevalent due to the structure of the package substrate. In some instances, the glass core substrate extends out past the edges of the overlying and underlying buildup layers. As such, an exposed portion of the glass core substrate is exposed and can be easily impacted during assembly operations. In order to provide additional protection, some designs have incorporated a buffer layer over the exposed portion of the glass core substrate. An example of such a solution is shown in FIGS. 1A and 1B. Though, in architectures, the glass core edge and the edges of the buildup layers may be substantially coplanar. Even in such embodiments, the exposed edge surface of the glass core may benefit from additional protection provided by embodiments described herein.

Referring now to FIG. 1A, a cross-sectional illustration of a package substrate 100 is shown. As shown, the package substrate 100 may comprise a glass core substrate 105 with an overlying buildup layer 120 and an underlying buildup layer 120. The glass core substrate 105 may include a portion 104 that extends past an edge 121 of the buildup layers 120. That is, a portion of a top surface 107, a portion of a bottom surface 108, and a sidewall surface 106 of the glass core substrate 105 may be exposed. The exposed portion 104 may be susceptible to damage since it is unprotected.

Referring now to FIG. 1B, a cross-sectional illustration of the package substrate 100 in FIG. 1A is shown after a buffer layer 110 is applied over the exposed portion 104 of the glass core substrate 105. As shown, the buffer layer 110 may conform to the exposed surfaces of the glass core substrate 105. The buffer layer 110 may be a dielectric material that is capable of absorbing impacts that may otherwise damage the glass core substrate 105. The buffer layer 110 may also provide protection to internal thermal mechanical stresses (e.g., generated due to coefficient of thermal expansion (CTE) mismatch and/or the like).

However, the buffer layer 110 may not have an edge 111 that is well defined. For example, the edge 111 in FIG. 1B is curved. In addition to the curvature of the edge 111 shown in FIG. 1B, the edge 111 may be curved in a plane orthogonal to the view of FIG. 1B (i.e., in a plan view looking down at the package substrate 100). The curvature of the buffer layer 110 may be the result of surface tension effects during the deposition of a liquid material. Prior to curing to form the solid buffer layer 110, the liquid material is free to flow in order to form a shape that minimizes surface energy. Further, in some instances, the buffer layer 110 may have a transparent (or relatively transparent) color, which is difficult to identify with optical imaging. The combined effects of a poorly defined linear edge and the transparent nature of the buffer layer 110 make handling the package substrate 100 with automated tool sets difficult.

Accordingly, embodiments disclosed herein may include a series of processes and/or architectures that allow for a more well-defined edge profile for the buffer layer. In one embodiment, the edge profile is set to be substantially vertical due to the presence of a rigid frame. In another embodiment, a gas pressing operation is used to maintain a linear edge during the curing process. In yet another embodiment, the geometry of the glass core substrate is biased in order to account for the surface tension effects of the liquid adhesive in order to provide linear edges. In another embodiment, a roller coating process with a scraping tool may be used in order to provide a well-defined edge profile for the buffer layer. Embodiments may also comprise a vacuum assisted scraper in order to improve the profile of the buffer layer.

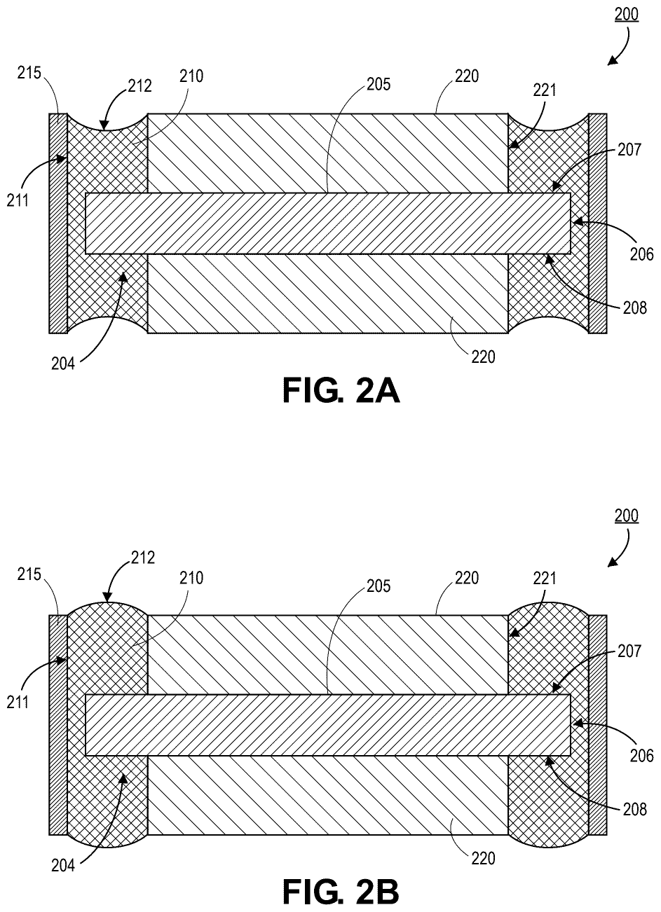

Referring now to FIGS. 2A and 2B, a pair of cross-sectional illustrations of a package substrate 200 with a buffer layer 210 that is retained by a frame 215 is shown, in accordance with an embodiment.

Referring now to FIG. 2A, a cross-sectional illustration of a package substrate 200 is shown, in accordance with an embodiment. In an embodiment, the package substrate 200 may comprise a panel form factor, a quarter panel form factor, or a unit form factor. In an embodiment, the package substrate 200 may comprise a glass core substrate 205 that is provided between organic buildup layers 220.

In an embodiment, the glass core substrate 205 may be substantially all glass. The glass core substrate 205 may be a solid mass comprising a glass material with an amorphous crystal structure where the solid glass core may also include various structures - such as vias, cavities, channels, or other features—that are filled with one or more other materials (e.g., metals, metal alloys, dielectric materials, etc.). As such, the glass core substrate 205 may be distinguished from, for example, the “prepreg” or “FR4” core of a Printed Circuit Board (PCB) substrate which typically comprises glass fibers embedded in a resinous organic material, such as an epoxy.

The glass core substrate 205 may have any suitable dimensions. In a particular embodiment, the glass core substrate 205 may have a thickness that is approximately 50 μm or greater. For example, the thickness of the glass core substrate 205 may be between approximately 50 μm and approximately 1.4 mm. Though, smaller or larger thicknesses may also be used. The glass core substrate 205 may have edge dimensions (e.g., length, width, etc.) that are approximately 10 mm or greater. For example, edge dimensions may be between approximately 10 mm to approximately 250 mm. Though, larger or smaller edge dimensions may also be used. More generally, the area dimensions of the glass core substrate 205 (from an overhead plan view) may be between approximately 10 mm×10 mm and approximately 250 mm×250 mm. In an embodiment, the glass core substrate 205 may have a first side that is perpendicular or orthogonal to a second side. In a more general embodiment, the glass core substrate 205 may comprise a rectangular prism volume with sections (e.g., vias) removed and filled with other materials (e.g., metal, etc.).

The glass core substrate 205 may comprise a single monolithic layer of glass. In other embodiments, the glass core substrate 205 may comprise two or more discrete layers of glass that are stacked over each other. The discrete layers of glass may be provided in direct contact with each other, or the discrete layers of glass may be mechanically coupled to each other by an adhesive or the like. The discrete layers of glass in the glass core substrate 205 may each have a thickness less than approximately 50 μm. For example, discrete layers of glass in the glass core substrate 205 may have thicknesses between approximately 25 μm and approximately 50 μm. Though, discrete layers of glass may have larger or smaller thicknesses in some embodiments. As used herein, “approximately” may refer to a range of values within ten percent of the stated value. For example approximately 50 μm may refer to a range between 45 μm and 55 μm.

The glass core substrate 205 may be any suitable glass formulation that has the necessary mechanical robustness and compatibility with semiconductor packaging manufacturing and assembly processes. For example, the glass core substrate 205 may comprise aluminosilicate glass, borosilicate glass, alumino-borosilicate glass, silica, fused silica, or the like. In some embodiments, the glass core substrate 205 may include one or more additives, such as, but not limited to, Al₂O₃, B₂O₃, MgO, CaO, SrO, BaO, SnO₂, Na₂O, K₂O, SrO, P₂O₃, ZrO₂, Li₂O, Ti, or Zn. More generally, the glass core substrate 205 may comprise silicon and oxygen, as well as any one or more of aluminum, boron, magnesium, calcium, barium, tin, sodium, potassium, strontium, phosphorus, zirconium, lithium, titanium, or zinc. In an embodiment, the glass core substrate 205 may comprise at least 23 percent silicon (by weight) and at least 26 percent oxygen (by weight). In some embodiments, the glass core substrate 205 may further comprise at least 5 percent aluminum (by weight).

In the embodiment shown in FIG. 2A, electrical routing (e.g., pads, traces, vias, etc.) are omitted for simplicity. However, it is to be appreciated that electrically conductive vias may be formed through a thickness of the glass core substrate 205, and other electrical routing may be provided within the buildup layers 220. The buildup layers 220 may comprise a plurality of laminated organic dielectric layers, such as organic buildup film or the like.

In an embodiment, the glass core substrate 205 may comprise a portion 204 that extends past an edge 221 of the buildup layers 220. For example, the glass core substrate 205 may have a width that is greater than a width of one or both of the buildup layers 220. In an embodiment, the portion 204 that extends beyond the buildup layers 220 may include a top surface 207, a bottom surface 208, and an edge surface 206. In the illustrated embodiment, the edge surface 206 is substantially orthogonal to the top surface 207 and/or the bottom surface 208 (i.e., the edge surface 206 may be referred to as being “substantially vertical”). Though, in other embodiments, the edge surface 206 may be sloped, curved, or otherwise non-orthogonal to the top surface 207 and/or the bottom surface 208. As shown, the edge surface 206 may be offset from the edge 221 of one or both of the buildup layers 220.

In an embodiment, the portion 204 that extends beyond the edges 221 of the buildup layers 220 may be embedded in a buffer layer 210. The buffer layer 210 may be a dielectric material that is applied with any suitable process. For example, the buffer layer 210 may comprises one or more of an epoxy, an acrylic, a urethane, a polyimide, or the like. In some embodiments, the buffer layer 210 is a material that can be cured with an ultraviolet (UV) exposure process. The buffer layer 210 may be applied in a liquid form with a roller coating process that is followed by a curing operation.

In the embodiment shown in FIG. 2A, the buffer layer 210 has a height that is substantially equal to a combined height of the glass core substrate 205 and the two buildup layers 220. Though, in other embodiments, the buffer layer 210 may be shorter than the combined height of the glass core substrate 205 and the two buildup layers 220. That is, the buffer layer 210 may cover an entire edge 221 of one or both buildup layers 220, or the buffer layer 210 may cover a portion of the edge 221 of one or both buildup layers 220.

In an embodiment, an outer edge 211 of the buffer layer 210 is confined by a frame 215 that wraps around a perimeter of the package substrate 200. The frame 215 may comprise a rigid material, such as a metal (e.g., copper, aluminum, etc.) or a rigid thermoset plastic frame (e.g., epoxy, polyimide, etc.). In an embodiment, the height of the frame 215 may be similar to a combined height of the package substrate 200, or the height of the frame 215 may be smaller than a combined height of the package substrate 200. The rigid frame 215 provides a barrier that prevents the buffer layer 210 from flowing into a curved shape to minimize surface tension while in a liquid state. Accordingly, the package substrate 200 is provided with a well-defined edge that can be easily identified and handled by automated material handling equipment and/or tools.

While the frame 215 provides confinement along the outer edge 211 of the buffer layer 210, the upper and lower surfaces 212 of the buffer layer 210 may not be confined. As such, the upper and lower surfaces 212 may comprise a curved profile. For example, in FIG. 2A, the upper and lower surfaces 212 exhibit a concave curvature. Alternatively, FIG. 2B illustrates a cross-sectional illustration of the package substrate 200 where the upper and lower surfaces 212 of the buffer layer 210 exhibit a convex curvature.

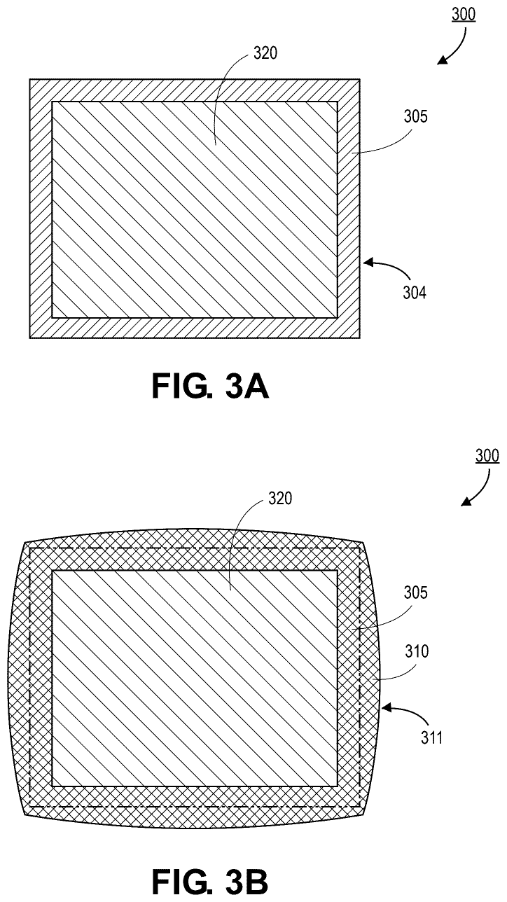

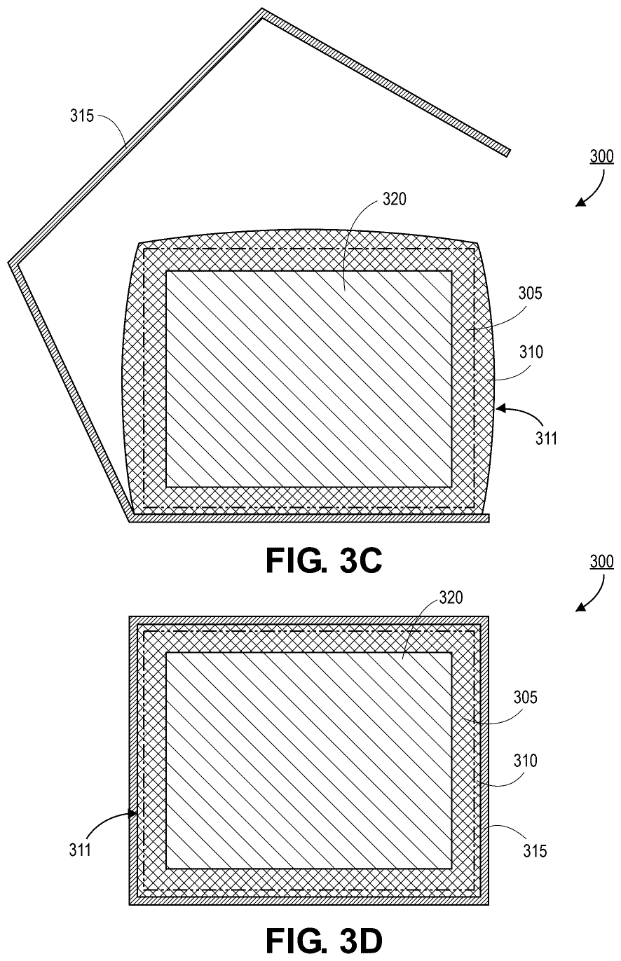

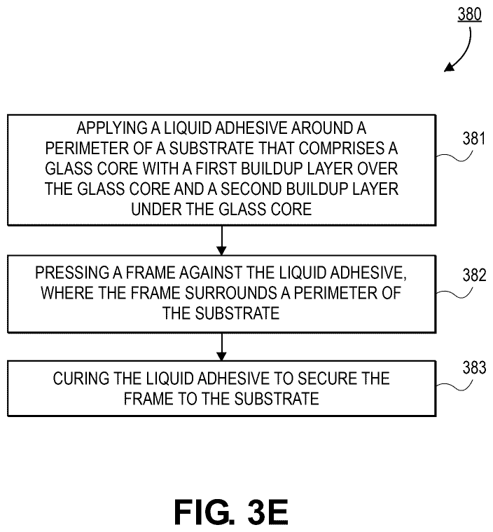

Referring now to FIG. 3A-3D, a series of plan view illustrations depicting a process for forming a package substrate 300 with a buffer layer 310 that includes a well-defined outer edge 311 is shown, in accordance with an embodiment.

Referring now to FIG. 3A, a plan view illustration of a package substrate 300 is shown, in accordance with an embodiment. As shown, a buildup layer 320 is provided over a glass core substrate 305. A portion 304 of the glass core substrate 305 may extend out beyond the edges of the buildup layer 320. In an embodiment, the buildup layer 320 and the glass core substrate 305 may be similar to the buildup layer 220 and the glass core substrate 205 described in greater detail above.

Referring now to FIG. 3B, a plan view illustration of the package substrate 300 after a buffer layer 310 (in a liquid form) is applied over the portion 304 of the glass core substrate 305 (indicated with the dashed line) is shown, in accordance with an embodiment. In an embodiment, the buffer layer 310 may be applied with a roller coating process or the like. As shown, surface tension effects due to the liquid nature of the buffer layer 310 may result in the edges 311 curving out away from the edge of the glass core substrate 305.

Referring now to FIG. 3C, a plan view illustration of the package substrate 300 as a frame 315 is being applied around the package substrate 300 is shown, in accordance with an embodiment. In the illustrated embodiment, the frame 315 is a continuous structure that is wrapped around a perimeter of the buffer layer 310. Though, in other embodiments, the frame 315 may comprise a plurality of discrete segments that attach together around the perimeter of the buffer layer 310. For example, each of the four edges 311 of the buffer layer 310 may be pressed by a discrete segment of the frame 315.

Referring now to FIG. 3D, a plan view illustration of the package substrate 300 after the frame 315 is pressed against all of the edges 311 of the buffer layer 310 is shown, in accordance with an embodiment. As shown, the frame 315 confines the flow of the liquid buffer layer 310 and results in the edges 311 being substantially linear. At this point, the liquid buffer layer 310 may be cured (e.g., with one or more of a UV curing process, a thermal curing process, or the like) in order to turn the buffer layer 310 into a solid material. In an embodiment, the buffer layer 310 may be a material similar to any of the buffer layer materials described in greater detail herein.

Referring now to FIG. 3E, a flow diagram depicting a process 380 for forming a package substrate with well defined edges through the use of a frame is shown, in accordance with an embodiment. In an embodiment, the process 380 may be similar to the process described above with respect to FIG. 3A-3D. In an embodiment, the process 380 may begin with operation 381, which comprises applying a liquid adhesive around a perimeter of a substrate that comprises a glass core with a first buildup layer over the glass core and a second buildup layer under the glass core. In an embodiment, the liquid adhesive may be a curable material that is applied with a roller coating process, or the like.

In an embodiment, the process 380 may continue with operation 382, which comprises pressing a frame against the liquid adhesive. In an embodiment, the frame surrounds a perimeter of the substrate. The frame may press against the liquid adhesive in order to set a linear edge for the liquid adhesive. The frame may be similar to any of the frames described in greater detail herein.

In an embodiment, the process 380 may continue with operation 383, which comprises curing the liquid adhesive to secure the frame to the substrate. In an embodiment, the curing process may include one or more of a UV curing process, a thermal curing process, or the like. The cured liquid adhesive may be a solid material that functions as a buffer layer to protect portions of the glass core that may protrude beyond an edge of the first buildup layer and/or the second buildup layer.

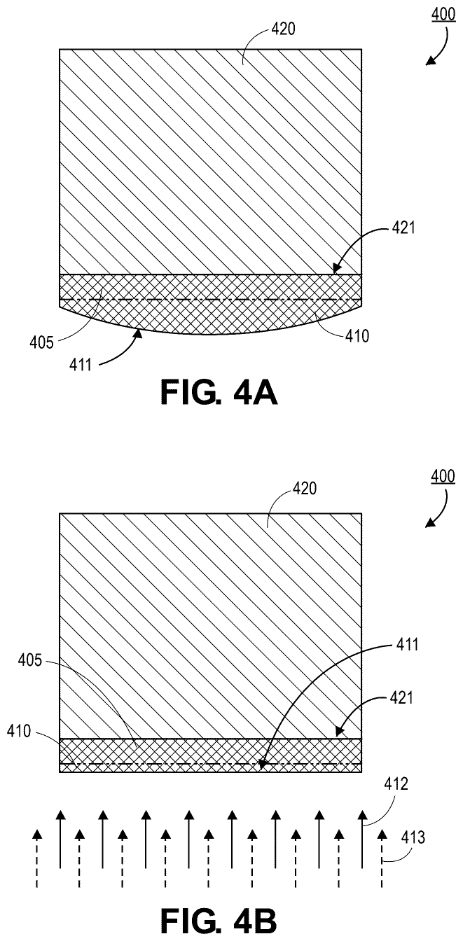

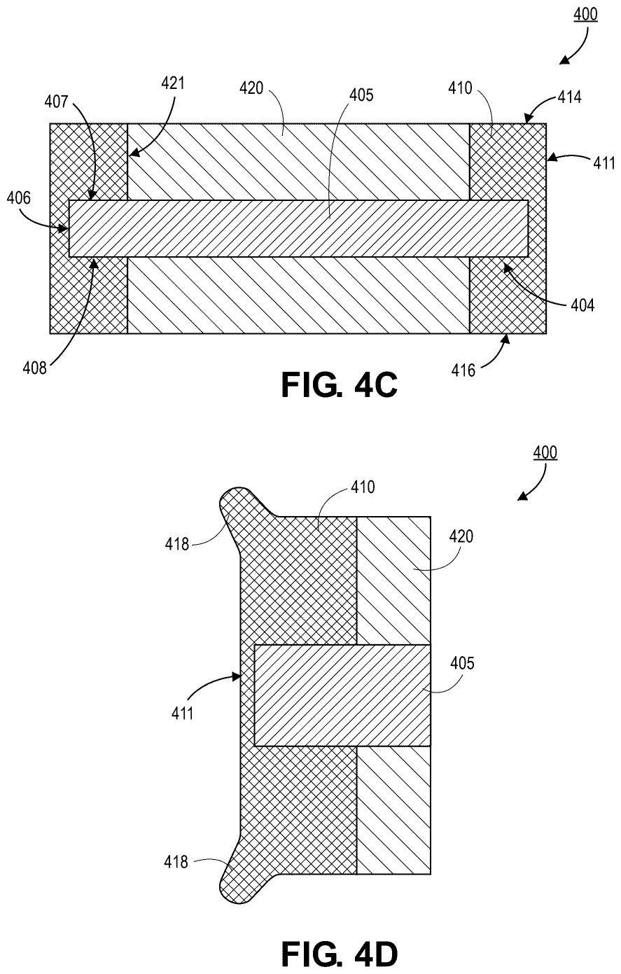

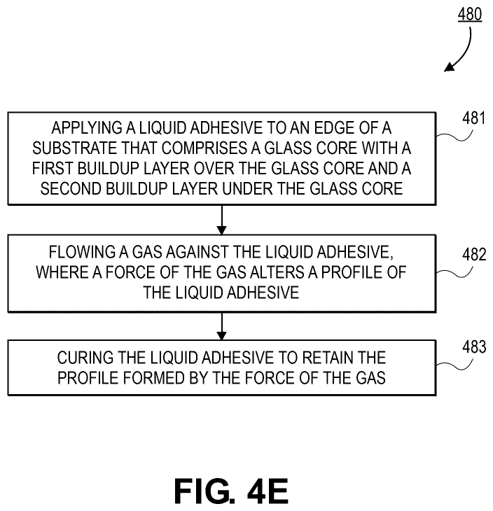

While a physical frame may be used in order to provide a well-defined edge for the buffer layer, other embodiments may include a package substrate with a well-defined edge without the addition of a retainment feature that persists into the final structure of the package substrate. For example, pressure may be applied to the liquid buffer layer in order to set a desired edge profile. In one such an embodiment, a gas pressing process may be used. An example of such an embodiment is shown in FIGS. 4A and 4B.

Referring now to FIG. 4A, a plan view illustration of a portion of a package substrate 400 is shown, in accordance with an embodiment. In an embodiment, the package substrate 400 may be similar to other package substrate described herein. For example, a glass core substrate 405 (indicated by the dashed line) may protrude beyond an edge 421 of an overlying and/or underlying buildup layer 420. The glass core substrate 405 and the buildup layers 420 may be similar to any of the glass core substrates and/or buildup layers described in greater detail herein.

In an embodiment, a liquid based buffer layer 410 may be applied over the protruding portion of the glass core substrate 405. In the illustrated embodiment, a single edge 411 of the buffer layer 410 is shown for simplicity. Though, it is to be appreciated that the buffer layer 410 may surround a perimeter of the package substrate 400 similar to other embodiments described herein. As shown, the surface tension effects due to the liquid nature of the buffer layer 410 may result in a non-linear (i.e., curved) edge 411.

Referring now to FIG. 4B, a plan view illustration of the portion of the package substrate 400 while a gas pressing operation and curing operation are implemented is shown, in accordance with an embodiment. In an embodiment, the gas pressing operation may include flowing a gas 412 against the edge 411 of the buffer layer 410. The force of the gas 412 may set a new profile for the edge 411, such as a substantially linear profile that is parallel to the edge 421 of the buildup layer 420. After the desired profile of the edge 411 of the buffer layer 410 is set, a curing process 413 (e.g., a UV cure, a thermal cure, or the like) may be implemented while the gas 412 continues to flow to maintain the desired profile through the cure. After the buffer layer 410 is converted into a solid layer, the gas press may be stopped.

In some embodiments, the gas pressing may be implemented along all edges 411 of the buffer layer 410 (e.g., around an entire perimeter of the package substrate 400) at the same time. In other embodiments, each edge 411 of the buffer layer 410 may be set and cured in a sequential manner. In yet another embodiment, portions of an edge 411 of the buffer layer 410 may be set and cured in a sequential manner.

Referring now to FIGS. 4C and 4D, a pair of cross-sectional illustrations illustrate various profiles of the edge 411 of the buffer layer 410 along a plane orthogonal to the plane of FIG. 4B. As shown in FIG. 4C, the buffer layer 410 may have a height that is substantially equal to a combined height of the package substrate 400 (i.e., a combined height of the two buildup layers 420 and the glass core substrate 405. Though, in other embodiments, the height of the buffer layer 410 may be smaller than the combined height of the package substrate 400 or greater than the combined height of the package substrate. As shown, an inner surface of the buffer layer 410 may conform to the edge 421 of the buildup layers 420 and the surfaces (e.g., the top surface 407, the bottom surface 408, and the edge surface 406 of the portion 404 that extends beyond the buildup layers 420) of the glass core substrate 405. In some embodiments, at least a portion of the edge 411 of the buffer layer 410 is substantially parallel to the edge surface 406 of the glass core substrate 405.

In an embodiment, the exposed surfaces of the buffer layer 410 may have substantially the same surface roughness. For example, the top surface 414, the bottom surface 416 and the edge 411 of the buffer layer 410 may all have substantially the same surface roughness. The similarity in surface roughness between all of the exposed surfaces is the result of the processing used to define the vertical edge 411. Since a non-contact process (i.e., no physical contact with a solid material) is used to set the profile of the buffer layer 410, there is no physical damage to any of the surfaces 414, 416, or edge 411. That is, a cutting or singulation process that would roughen the surface is not needed to form the vertical edge 411. Similarly, a molding process would leave behind artifacts due to surface roughness of the mold or damage to the edge 411 during mold removal.

While a purely vertical edge 411 is shown in FIG. 4C, some embodiments may include an edge 411 that is only a partially vertical. An example of such an embodiment is shown in FIG. 4D. As shown in FIG. 4D, the buffer layer 410 may comprise a pair of protrusions 418 that are provided at the top and bottom of the buffer layer 410. That is, the protrusions 418 may be provided on opposite sides of the glass core substrate 405. In an embodiment, the protrusions 418 may be the result of the gas pressing process. Due to the force applied by the gas, some portions of the liquid may be forced up and away from the linear portion of the edge 411. Such a profile may sometimes be referred to as having a bowl shape or a bowl-like shape. That is, the vertically liner portion of the edge 411 may be a bottom of the bowl, and the protrusions 418 may define the sidewalls of the bowl.

Referring now to FIG. 4E, a flow diagram of a process 480 for forming a package substrate with a buffer layer using a gas pressing operation is shown, in accordance with an embodiment. In an embodiment, the process 480 may be similar to the process described with respect to FIGS. 4A and 4B described herein.

In an embodiment, the process 480 may begin with operation 481, which comprises applying a liquid adhesive to an edge of a substrate that comprises a glass core with a first buildup layer over the glass core and a second buildup layer under the glass core. In an embodiment, the liquid adhesive may be applied with a roller coating process or the like. In an embodiment, the substrate may be similar to any of the package substrates described in greater detail herein.

In an embodiment, the process 480 may continue with operation 482, which comprise flowing a gas against the liquid adhesive. In an embodiment, a force of the gas alters a profile of the liquid adhesive. In an embodiment, the gas may be orthogonally directed at the edge of the liquid adhesive. Though, the gas may be flown at the edge of the liquid adhesive with other angles as well. In an embodiment, the gas may comprise air, an inert gas, or any other suitable gas. In an embodiment, the profile may provide an edge with a vertical portion. In some embodiments, the profile may have a bowl-like shape.

In an embodiment, the process 480 may continue with operation 483, which comprises curing the liquid adhesive to retain the profile formed by the force of the gas. In an embodiment, the curing process may be implemented while the gas pressing operation is still being implemented. The curing process may include a UV cure, a thermal cure, or the like.

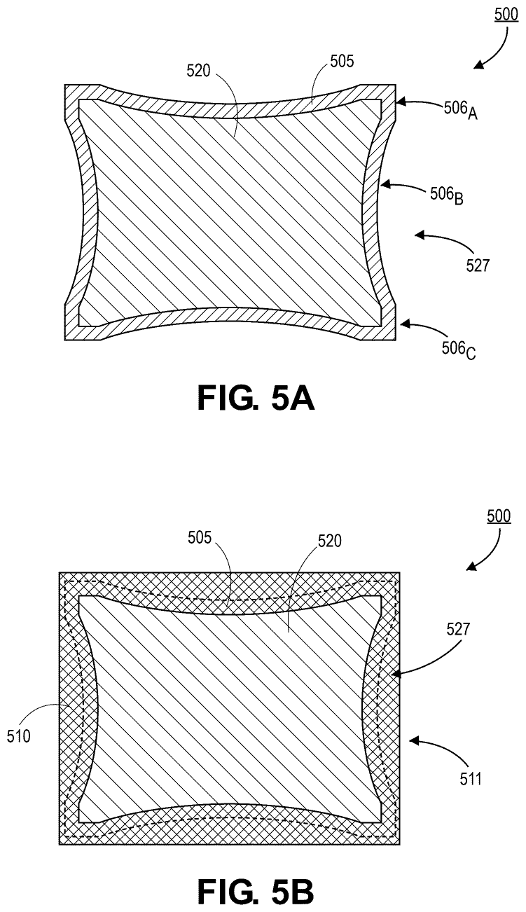

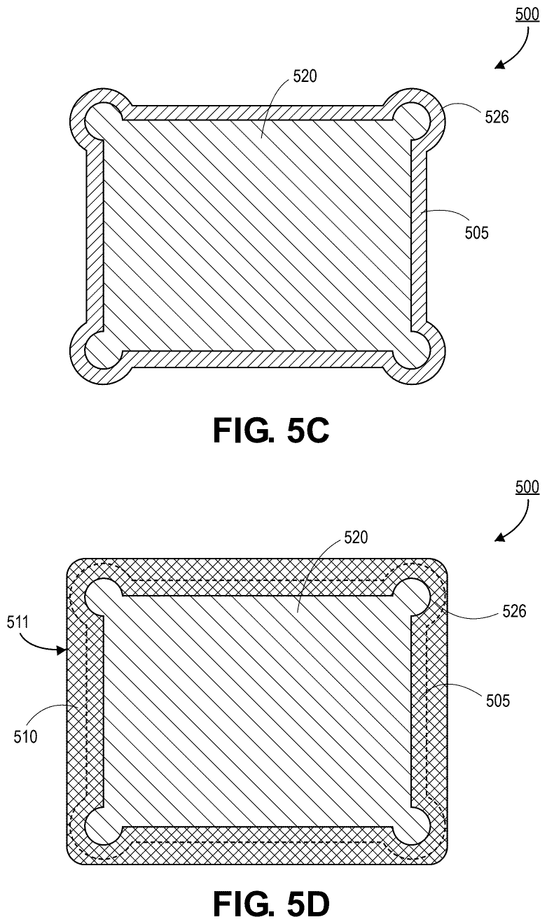

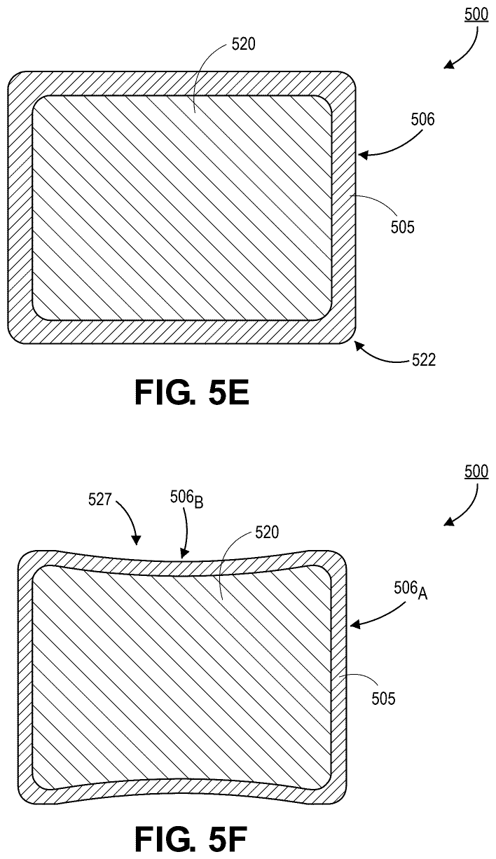

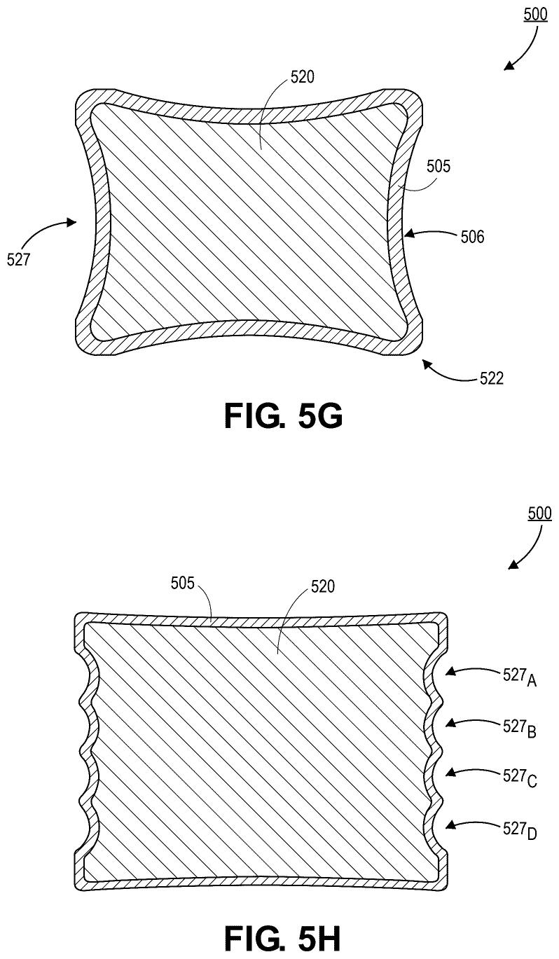

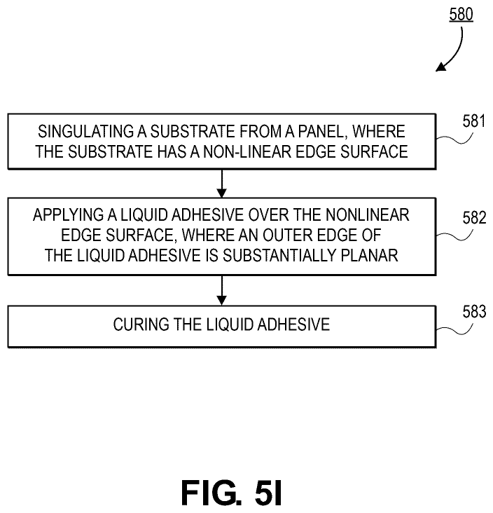

In yet another embodiment, the profile of the edge of the buffer layer may be controlled through modification of surfaces of the glass core substrate and/or the buildup layers. For example, the profile of edge of the glass core substrate may be curved or otherwise biased in order to account for the surface tension effects of the buffer layer when in the liquid form. As such, the liquid buffer layer may have a relatively linear edge without the application of an external force, such as a physical frame or mold, a gas pressing operation, and/or the like. Examples of such embodiments are shown in FIG. 5A-5H.

Referring now to FIG. 5A, a plan view illustration of a package substrate 500 is shown, in accordance with an embodiment. In an embodiment, the package substrate 500 may comprise a glass core substrate 505 with buildup layers 520 over and/or under the glass core substrate 505. The glass core substrate 505 and the buildup layers 520 may be similar to any of the glass core substrates or buildup layers described in greater detail herein. As shown, a portion of the glass core substrate 505 may extend out beyond an edge of the buildup layer 520. That is, a width of the glass core substrate 505 may be greater than a width of the buildup layer 520 in some embodiments.

In contrast to some other embodiments described herein, an edge 506 of the glass core substrate 505 may include a non-linear profile. For example, the right edge 506 in FIG. 5A may comprise a depression 527 with a curved portion of the edge 506_{B}. In some instances, the curved portion of the edge 506_{B} may be referred to as having a concave shape. In some embodiments, the linear portions of the edge 506_{A} and 506_{C} may also be provided along the right edge 506 of the glass core substrate 505. That is, one or more edges 506 of the glass core substrate 505 may comprise both linear and non-linear portions. In the embodiment shown in FIG. 5A, each edge 506 around a perimeter of the glass core substrate 505 comprises a depression 527. Though, embodiments may include depressions 527 along any number of the edges 506 around the perimeter of the glass core substrate 505. In some embodiments, the glass core substrate 505 may have depressions 527 that are oriented so that the glass core substrate 505 is symmetric about a line that passes through a center of the glass core substrate 505.

In an embodiment, the edges of the buildup layer 520 may also include a curved surface to substantially match a profile of the edges 506 of the glass core substrate 505. Though, in other embodiments, the buildup layer 520 may have edges that do not substantially match the profile of the edges 506 of the glass core substrate 505.

Referring now to FIG. 5B, a plan view illustration of the package substrate 500 of FIG. 5A after a buffer layer 510 is applied is shown, in accordance with an embodiment. In an embodiment, the buffer layer 510 may comprise any suitable buffer layer material, such as any of those described in greater detail herein. For example, the buffer layer 510 may comprise one or more of an epoxy, an acrylic, a urethane, or a polyimide. The buffer layer 510 may be applied as a liquid (e.g., a liquid adhesive) and cured to form the solid buffer layer 510. As shown, the depressions 527 may be designed so that the surface tension effects of the liquid buffer layer 510 result in linear edges 511 for the buffer layer 510. That is, the natural state of the liquid buffer layer 510 will form the linear edge 511 without the application of any external force. A curing process (e.g., a UV cure, a thermal cure, or the like) may be used to set the profile of the edges 511 of the buffer layer 510.

Referring now to FIG. 5C, a plan view illustration of package substrate 500 is shown, in accordance with an additional embodiment. In an embodiment, the package substrate 500 in FIG. 5C may be similar to the package substrate 500 in FIG. 5A, with the exception of protrusions 526 being used instead of depressions. For example, circular protrusions 526 may be provided at corners of the glass core substrate 505. While shown as being partial circle-like structures, it is to be appreciated that protrusions with any shape may be provided at the corners of the glass core substrate 505 in other embodiments.

Referring now to FIG. 5D, a plan view illustration of the package substrate 500 after the buffer layer 510 is applied is shown, in accordance with an embodiment. As shown, the buffer layer 510 may have substantially linear edges 511. The linear edges 511 are enabled by the protrusions 526 biasing the liquid material of the buffer layer 510 in order to negate the effects of surface tension. As such, the as-deposited buffer layer 510 liquid may form the linear edges 511 without the application of any external force. A curing process (e.g., a UV cure, a thermal cure, or the like) may set the shape of the buffer layer 510.

Referring now to FIG. 5E-5H, a series of plan view illustrations of various package substrates 500 are shown, in accordance with additional embodiments. In an embodiment, the package substrates 500 in FIG. 5E-5H may be similar to those in FIG. 5A-5D, with the exception of the profile of the edges 506 of the glass core substrate 505. However, it is to be appreciated that such profiles shown in FIG. 5E-5H may be engineered in order to bias the buffer layer (not shown) in order to generate linear edges without the application of external force.

Referring now to FIG. 5E, a plan view illustration of a package substrate 500 is shown, in accordance with an embodiment. As shown, the package substrate 500 may comprise a glass core substrate 505 that has rounded corners 522 and a first edge 506. The rounded corners 522 may contribute to the formation of linear edges of the buffer layer (not shown).

Referring now to FIG. 5F, a plan view illustration of a package substrate 500 is shown, in accordance with an additional embodiment. As shown, the glass core substrate 505 may comprise first edges 506_{A} (i.e., the left and right edges 506) that are substantially linear and second edges 506_{B} (i.e., the top and bottom edges 506) that are curved. In some embodiments, the package substrate 500 may be considered as being mirrored or symmetric. That is, a left half of the package substrate 500 may be a mirror image of the right half of the package substrate 500.

Referring now to FIG. 5G, a plan view illustration of a package substrate 500 is shown, in accordance with an additional embodiment. As shown, the package substrate 500 in FIG. 5G may be similar to the package substrate 500 in FIG. 5A, with the exception of the corners 522. Instead of the corners being roughly ninety degrees, the corners 522 in FIG. 5G are rounded. The rounded profile of the corners 522 may further enhance the ability to form linear edges for the buffer layer (not shown). In an embodiment, the rounded corners may be coupled together by edges 506 that comprise depressions 527 or are otherwise curved.

Referring now to FIG. 5H, a plan view illustration of a package substrate 500 is shown, in accordance with an additional embodiment. In an embodiment, the package substrate 500 may comprise a plurality of depressions 527 along a single edge of the glass core substrate 505. For example, FIG. 5H illustrates four depressions 527_{A}-527_{D}. In some embodiments, such a multi-depression profile may sometimes be referred to as being a scalloped profile.

Referring now to FIG. 5I, a flow diagram of a process 580 for forming a package substrate with a buffer layer that includes linear edges is shown, in accordance with an embodiment. In an embodiment, the process 580 may begin with operation 581, which comprises singulating a substrate from a panel. In an embodiment, the substrate may have a non-linear edge surface. The substrate may comprise a package substrate similar to any of the package substrates 500 described herein. For example, the substrate may comprise a glass core substrate that extends past edges of overlying and/or underlying buildup layers. In an embodiment, the singulation process may include a laser ablation process, an etching process, or the like. The non-linear edge surface may include one or more curves, rounded corners, and/or the like.

In an embodiment, the process 580 may continue with operation 582, which comprises applying a liquid adhesive over the linear edge surface. In an embodiment, an outer edge of the liquid adhesive is substantially planar. For example, the surface tension effects of the liquid adhesive may drive the liquid adhesive to have a linear edge profile in response to the engineered shape of the non-linear edge of the substrate. Accordingly, no external forces may need to be applied in order to provide a linear edge for the substrate. In an embodiment, the liquid adhesive may be applied with a roller coating process or the like.

In an embodiment, the process 580 may continue with operation 583, which comprises curing the liquid adhesive. The curing process may include one or more of a UV curing process, a thermal curing process, or the like. After curing, the liquid adhesive converts into a solid buffer layer over the edge of the substrate.

Embodiments disclosed herein may include applying the buffer layer (or coating) around the package substrate in order to protect exposed portions of the glass core substrate. Typically, the buffer layer may be applied with a liquid based process. After the liquid is applied, a curing process is used to convert the material into the solid buffer layer. In some embodiments, roller coating has been described as one process for applying the buffer layer.

Embodiments disclosed herein may further include a roller coating process and/or system that enables more efficient and precise application of the buffer layer over the exposed edge of the glass core substrate. For example, a system that can process trays of unit level package substrates may be used in order to provide the sidewall coating with tight thickness and profile control. This may provide significant yield benefits due to better control of the protective buffer layer. Such a system that uses automated processing may also significantly improve throughput of the buffer layer coating process.

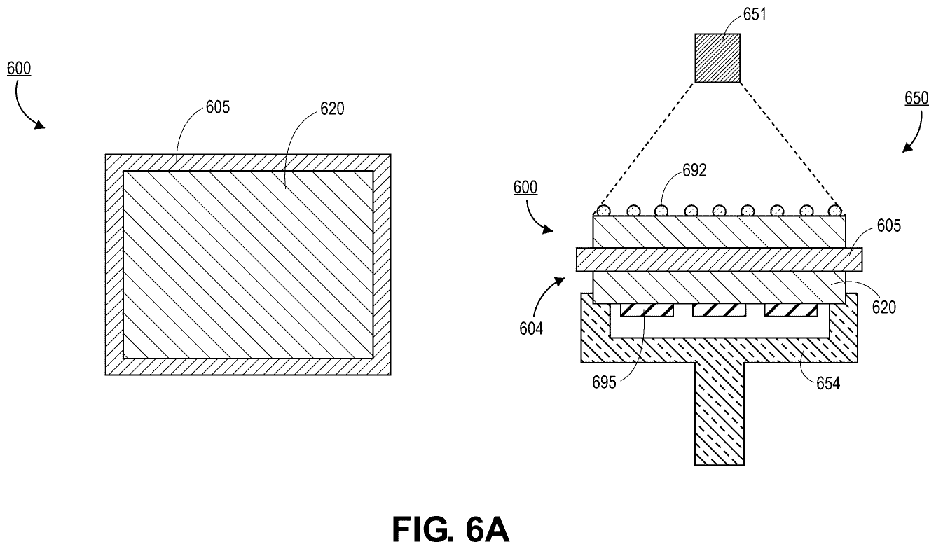

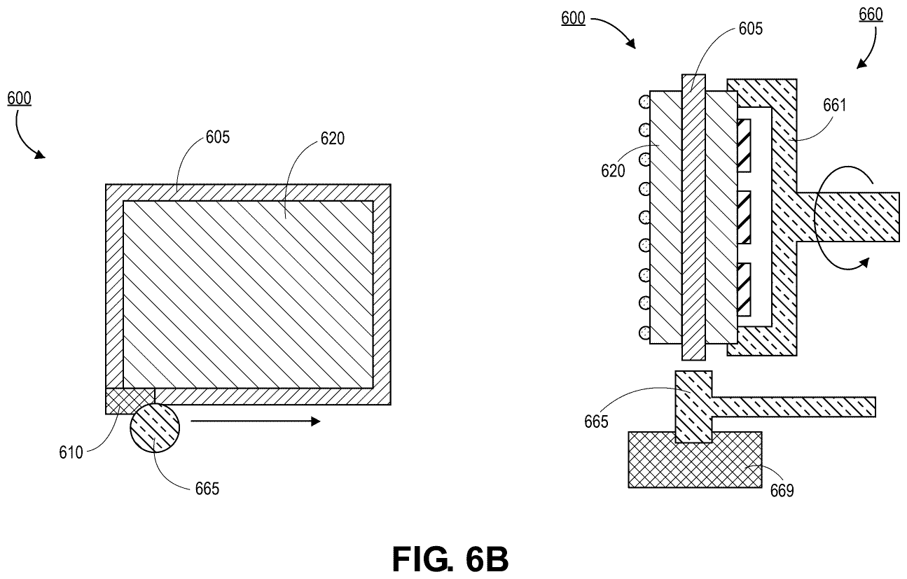

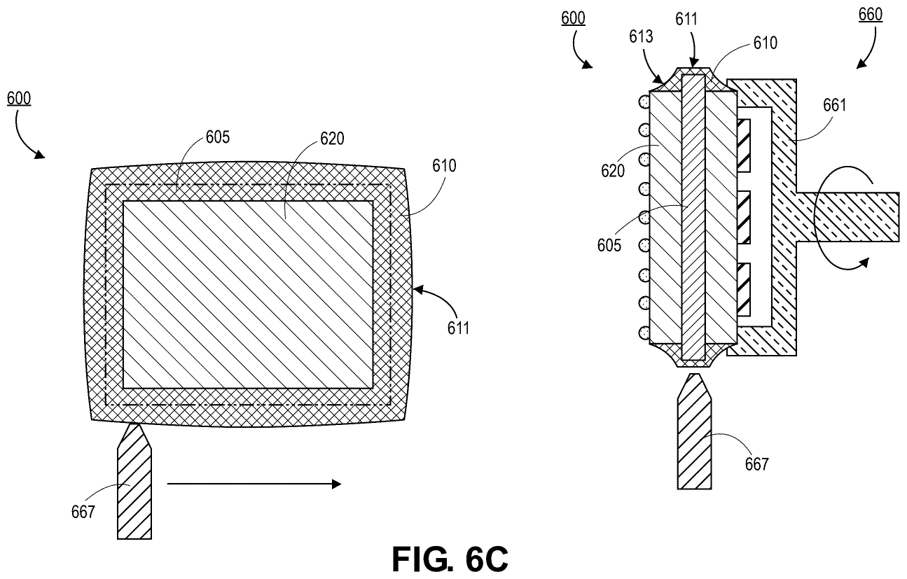

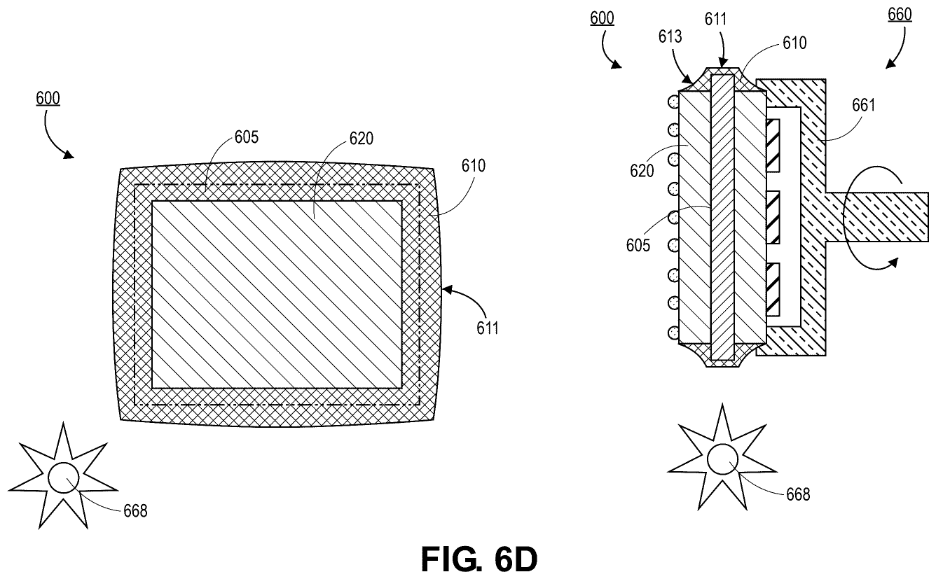

Referring now to FIG. 6A-6D, a series of plan view (left) and corresponding cross-sectional (right) illustrations that depict a process for roller coating a buffer layer onto a package substrate with an exposed glass core substrate is shown, in accordance with an embodiment.

Referring now to FIG. 6A, the plan view illustration depicts a package substrate 600. The package substrate 600 may be similar to other package substrates described in greater detail herein. For example, the package substrate 600 may comprise a glass core substrate 605 and overlying and/or underlying buildup layers 620. The glass core substrate 605 may have a width that is greater than a width of the buildup layer 620, and an edge portion 604 of the glass core substrate 605 may be exposed. In an embodiment, the cross-sectional illustration depicts the package substrate 600 having one or more dies 695 and second level interconnects 692. The package substrate 600 may be provided within an inspection tool 650. The inspection tool 650 may include a mount 654 for holding the package substrate 600. In an embodiment, an optical sensor 651 (e.g., a camera, or the like) may be used to inspect contours, orientations, and check for any defects or the like before further processing. In other embodiments, an additional optical sensor (out of the plane of FIG. 6A and not visible) may inspect a sidewall view in order to check for any existing glass edge cracking and/or other defects.

Referring now to FIG. 6B, illustrations depicting the roller coating process are shown, in accordance with an embodiment. As shown, a liquid buffer layer 610 is being applied along the edges of the package substrate 600. For example, the liquid buffer layer 610 may cover the exposed portions 604 of the glass core substrate 605.

As shown, the roller coating tool 660 may comprise a roller 665 that is configured to pick up buffer layer 610 liquid from a reservoir 669 and apply the liquid to the edge of the glass core substrate 605. In an embodiment, a mount 661 (e.g., a vacuum mount) may hold the package substrate 600 so that the edge is aligned with the roller 665. The mount 661 may rotate in some embodiments.

Referring now to FIG. 6C, illustrations depicting a process for defining an edge profile of the buffer layer 610 are shown, in accordance with an embodiment. After the buffer layer 610 is applied along all of the edge surfaces of the package substrate 600, a scraper 667 may be used to set a profile of an edge 611 of the buffer layer 610. For example, the buffer layer 610 may have a tapered cross-sectional shape with the inner surface that contacts the package substrate 600 having a greater height than the edge 611 that faces away from the package substrate 600. Surfaces 613 that are connected to the edge 611 may be linear or curved.

In an embodiment, the scraper 667 may provide improved accuracy of the thickness of the buffer layer 610 over the edge surface of the glass core substrate 605. For example, a thickness of the buffer layer 610 between the edge of the glass core substrate 605 and the edge 611 of the buffer layer 610 may be up to approximately 20 μm, up to approximately 50 μm, or up to approximately 100 μm. Though, larger thicknesses may also be used in some embodiments.

As shown in the plan view of FIG. 6C, the buffer layer 610 may form a frame or ring-like structure around a perimeter of the package substrate 600. This allows for improved protection to the fragile glass core substrate 605. Further, in some embodiments, the edge 611 of the buffer layer 610 may be curved due to the effects of surface tension within the liquid material used for the buffer layer 610. However, other embodiments described herein may be used in combination with the roller coating process in order to provide linear edges 611.

Referring now to FIG. 6D, illustrations of the package substrate 600 after a curing process are shown, in accordance with an embodiment. As shown, the curing process may include a UV curing process. For example, UV radiation may be propagated from a UV source 668. The curing process may convert the liquid adhesive into a solid buffer layer 610 in order to provide protection to the glass core substrate 605 within the package substrate 600.

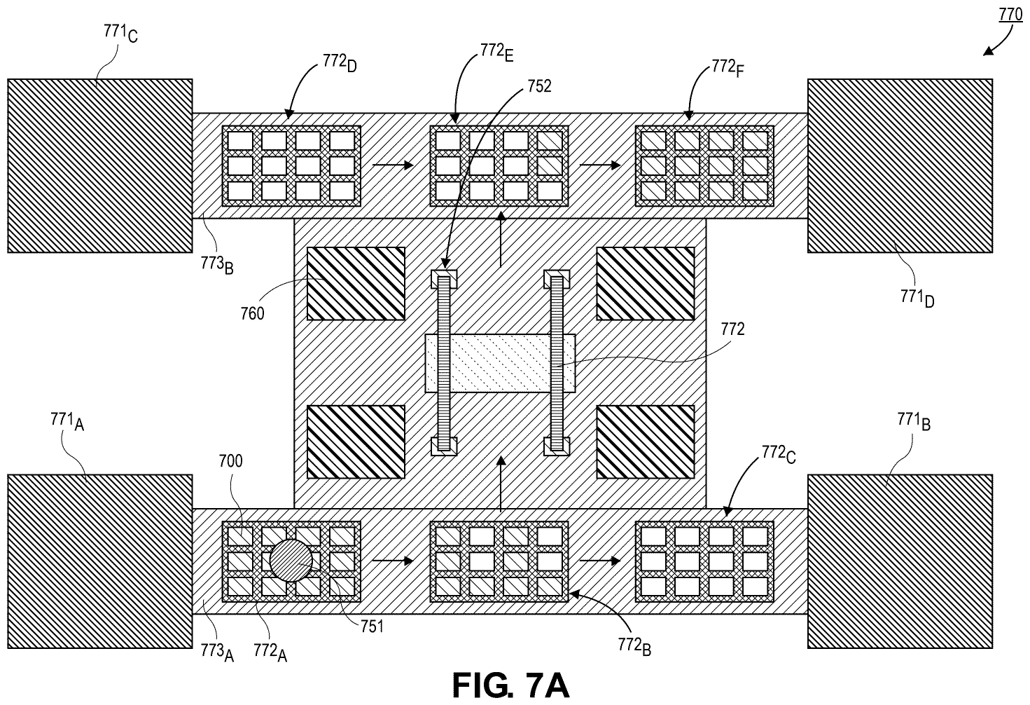

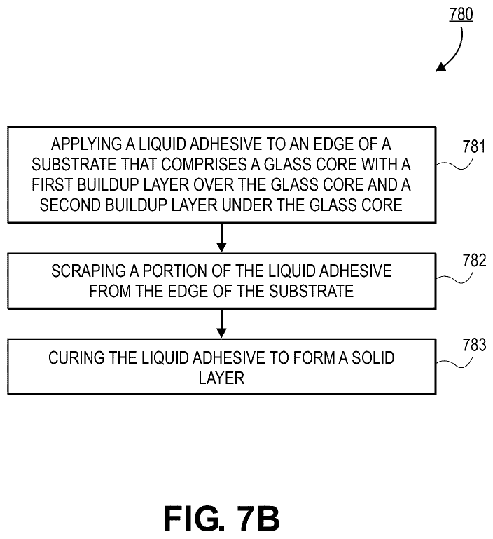

Referring now to FIG. 7A, a plan view schematic illustration of a tool 770 that may be used to implement roller coating processes (such as the one described with respect to FIG. 6A-6D) is shown, in accordance with an embodiment. In an embodiment, the tool 770 may comprise a plurality of tray stackers 771. For example, a set of four tray stackers 771_{A}-771_{D} are shown in FIG. 7A. A first tray stacker 771_{A} may include trays 772_{A} that are full of uncoated package substrates 700. The package substrates 700 may be similar to any of the package substrates described herein that include a glass core substrate. The second tray stacker 771_{B} may receive empty trays 772_{C}. For example, full trays 772_{A} may ride along a conveyor 773_{A}, and the individual package substrates 700 may be removed (e.g., as shown in tray 772_{B}) by a robot arm 772 for roller coating. In some embodiments, an inspection system 751 (e.g., an optical sensor, etc.) may be provided along the conveyor 773_{A} in order to check the units for orientation, gross defects, and/or the like.

In an embodiment, the robot arm 772 may retrieve the package substrate 700 units and deliver the package substrates to a roller coating tool 760. In the illustrated embodiment, a plurality of roller coating tools 760 are provided to increase throughput.

The roller coating tool 760 may operate in a manner similar to the roller coating tool 660 described above. For example, the roller coating tool 760 may include components to implement a liquid adhesive dispense process, a scraping process, and a curing process. After the coating is applied around an edge of the package substrate 700. An inspection 752 (e.g., with an optical sensor or the like) may be implemented before the robot arm loads the coated substrate 700 onto a tray 772_{E} that is on a conveyor 773_{B} between a third tray stacker 771_{C} and a fourth tray stacker 771_{D}. The third tray stacker 771_{C} may provide empty trays 772_{D}, and the fourth tray stacker 771_{D} may receive full trays 772_{F} that include coated package substrates 700.

Referring now to FIG. 7B, a flow diagram of a process 780 for forming a buffer layer coating along an edge of a glass core substrate within a package substrate is shown, in accordance with an embodiment. In an embodiment, the process 780 may begin with operation 781, which comprises applying a liquid adhesive to an edge of a substrate that comprises a glass core with a first buildup layers over the glass core and a second buildup layer under the glass core. In an embodiment, the substrate may be similar to any of the package substrates described herein. In an embodiment, an edge portion of the glass core may extend out beyond an edge of the buildup layers. In an embodiment, the liquid adhesive may be applied with a roller coating process, such as any of the roller coating processes described herein.

In an embodiment, the process 780 may continue with operation 782, which comprises scraping a portion of the liquid adhesive from the edge of the substrate. In an embodiment, the scraping process may result in a well-defined edge profile of the liquid adhesive with a uniform thickness over the outer edge of the glass core.

In an embodiment, the process 780 may continue with operation 783, which comprises curing the liquid adhesive to form a solid layer. In an embodiment, the curing process may comprise one or more of a UV curing process, a thermal curing process, or the like. The solid layer may be considered as a buffer layer and/or a coating that is a frame or ring around the outer perimeter of the substrate. The buffer layer may provide protection to the glass core in order to prevent damage, such as cracking, seware defects, and/or the like. In an embodiment, the buffer layer may comprise any suitable material that can be deposited as a liquid and cured to a solid, such as one or more of an epoxy, an acrylic, a urethane, or a polyimide.

In roller coating processes, such as those described herein, the design of the scraping tool may be used to set a desired edge profile for the buffer layer. Further, since the scraping tool is passing through a liquid material, after the scraping tool passes over a portion of the buffer layer, the liquid nature of the buffer layer may result in deformation from the desired profile. Accordingly, embodiments disclosed herein may include a scraping tool that provides better control of the edge profile through the use of a vacuum assisted scraping head. Further, an integrated UV light source may be coupled to the scaping tool in order to cure the buffer layer during the scraping process. Accordingly, the desired profile of the buffer layer can be formed by the scraping head and cured without significant deformation occurring.

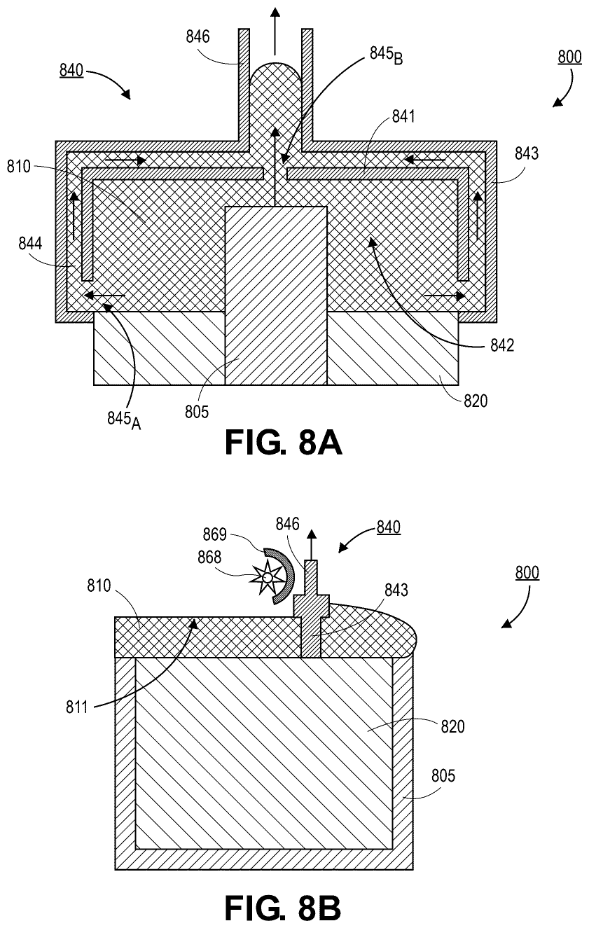

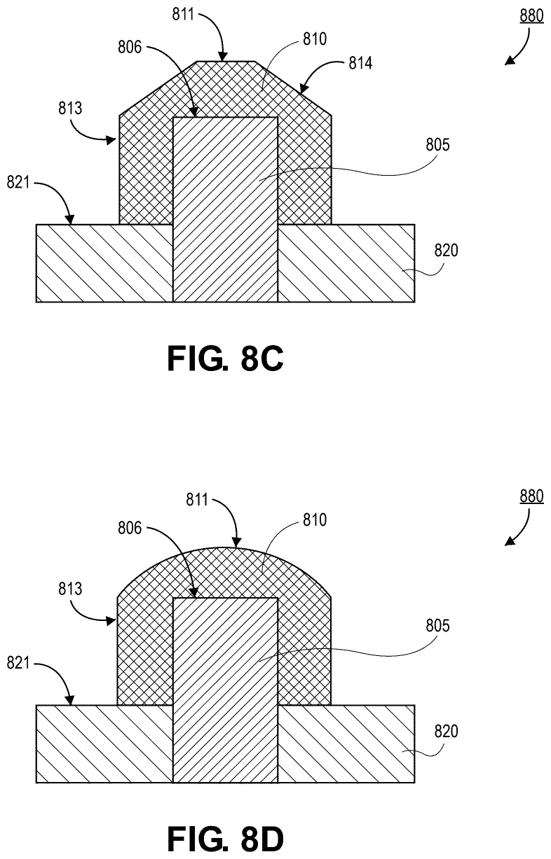

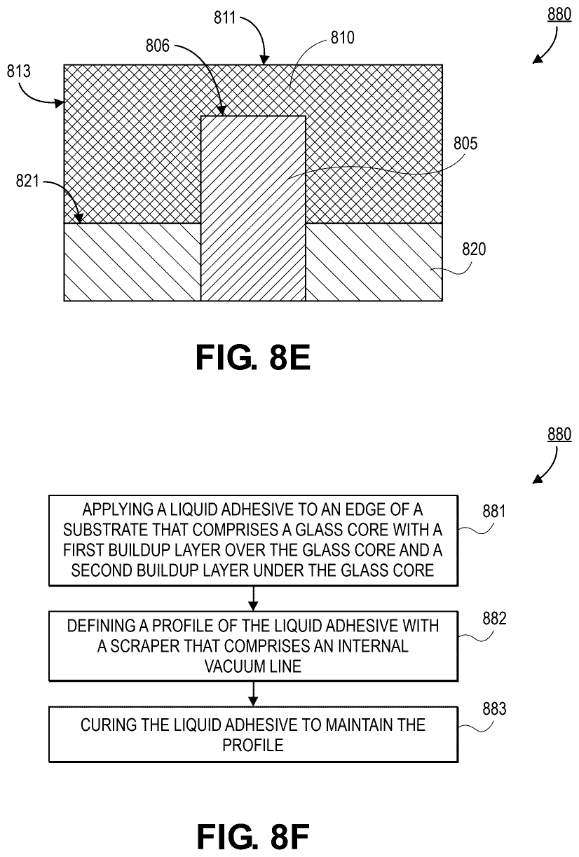

Referring now to FIG. 8A, a cross-sectional illustration of a portion of a package substrate 800 with a scraping tool 840 defining an edge profile of the buffer layer 810 is shown, in accordance with an embodiment. In an embodiment, the package substrate 800 may comprise a glass core substrate 805 with overlying and/or underlying buildup layers 820. The glass core substrate 805 and the buildup layers 820 may be similar to any of the glass core substrates and buildup layers described in greater detail herein.

In an embodiment, the scraping tool 840 may comprise a scraping head that includes an inner wall 841 and an outer wall 843. A gap 844 between the inner wall 841 and the outer wall 843 may be fluidically coupled to a vacuum line 846. A pump (not shown) that is coupled to the vacuum line 846 may pull a vacuum (e.g., reduce the pressure) within the gap 844. In an embodiment, one or more ports 845 may be provided through the inner wall 841 in order to pull liquid adhesive of the buffer layer 810 into the gap 844 (as indicated by the arrows). The force pulling the liquid buffer layer 810 outwards allows for the buffer layer 810 to fully fill a cavity 842 defined by the scraping head. As such, a desired profile can be provided. In the illustrated embodiment, ports 845_{A} may be provided along an edge of the inner wall 841, and a port 845_{B} may be provided along at an approximate midpoint of a top of the inner wall 841. Though, it is to be appreciated that any number of ports 845 and/or any location for the ports 845 may be used in accordance with various embodiments. In an embodiment, the cavity 842 may have any suitable depth, such as 25 μm or more, 50 μm or more, 100 μm or more, or 500 μm or more. Though, smaller depths for the cavity 842 may also be used in some embodiments.

In an embodiment, the scraping head may have an open bottom at the entrance to the cavity 842. Further, the scraping head may have open sides (out of the plane of FIG. 8A) that allow for the scraping head to move along the edge of the package substrate 800. In some embodiments, the scraping head may be referred to as being a C-shape, a half-pipe, or a partial tube-like structure with any desired cross-sectional shape.

Referring now to FIG. 8B, a plan view illustration of the package substrate 800 as the scraping tool 840 is used to define an edge surface 811 of the buffer layer 810 is shown, in accordance with an embodiment. As shown, the scraping tool 840 may include an outer wall 843 that passes laterally along the edge of the package substrate 800. The scraping tool 840 sets the profile of the edge surface 811. In some embodiments, an integrated UV light source 868 may be coupled to the scraping tool 840. As such, the edge surface 811 that is set by the scraping tool 840 can be set (e.g., nearly immediately after being formed) in order to prevent deformation of the edge surface 811 while still in a liquid form. Accordingly, substantially linear edge surfaces 811 can be provided in some embodiments. In an embodiment, the UV light source 868 may also include a shield 869. The shield 869 may be provided between the UV light source 868 and the scraping head. The shield 869 may prevent UV radiation from propagating ahead of the scraping tool 840. That is, the UV light source 868 may be configured to cure the buffer layer 810 after the edge surface 811 of the buffer layer is set.

It is to be appreciated that such a vacuum assisted scraping tool 840 has the flexibility to provide many different buffer layer 810 profiles. Several examples are shown in FIG. 8C-8E.

Referring now to FIG. 8C, a cross-sectional illustration of a portion of a package substrate 800 with a glass core substrate 805 and buildup layers 820 is shown, in accordance with an embodiment. As shown, the glass core substrate 805 may extend out past an edge surface 821 of the buildup layers 820. In order to protect the glass core substrate 805, a buffer layer 810 may be provided over the edge surface 806 of the glass core substrate 805. In an embodiment, the buffer layer 810 may have a vertical surface 813 that is substantially orthogonal to the edge surface 821 of the buildup layers 820, a sloped surface 814, and an edge surface 811. The edge surface 811 may be substantially parallel to the edge surface 806 of the glass core substrate 805. Further, a height of the buffer layer 810 (as measured between the vertical surfaces 813) may be smaller than a total height of the package substrate 800 (i.e., a combined height of the glass core substrate 805 and the buildup layers 820). In such an embodiment, portions of the edge surface 821 of the buildup layers 820 may be exposed.

Referring now to FIG. 8D, a cross-sectional illustration of a portion of a package substrate 800 is shown, in accordance with an additional embodiment. The package substrate 800 in FIG. 8D may be similar to the package substrate 800 in FIG. 8C, with the exception of the buffer layer 810. Instead of a linear edge surface 811, the edge surface 811 may be curved. The curved edge surface 811 may be directly connected to vertical surfaces 813 in some embodiments.

Referring now to FIG. 8E, a cross-sectional illustration of a portion of a package substrate 800 is shown, in accordance with an additional embodiment. The package substrate 800 in FIG. 8E may be similar to the package substrate 800 in FIG. 8C, with the exception of the shape of the buffer layer 810. In FIG. 8E, the buffer layer 810 may have a height that is substantially equal to the total height of the package substrate 800. That is, the buffer layer 810 may cover the entire length of the edge surface 821 of the buildup layer 820. Additionally, the edge surface 811 may intersect the vertical surfaces 813 at a substantially ninety-degree angle. In some embodiments, the buffer layer 810 may be considered as being rectangular in shape with a recess to accommodate the protruding portion of the glass core substrate 805.

Referring now to FIG. 8F, a flow diagram of a process 880 for forming a substrate with a buffer layer that has a defined edge profile is shown, in accordance with an embodiment. In an embodiment, the process 880 may begin with operation 881, which comprises applying a liquid adhesive to an edge of a substrate that comprises a glass core with a first buildup layer over the glass core and a second buildup layer under the glass core. In an embodiment, the substrate may be similar to any of the package substrates described herein. In an embodiment, an edge portion of the glass core may extend out beyond an edge of the buildup layers. In an embodiment, the liquid adhesive may be applied with a roller coating process, such as any of the roller coating processes described herein.

In an embodiment, the process 880 may continue with operation 882, which comprises defining a profile of the liquid adhesive with a scraper that comprises an internal vacuum line. In an embodiment, the scraper may be similar to the scraping tool 840 described herein. In an embodiment, the profile may include a profile similar to any of those described herein, such as those shown in FIG. 8C-8E.

In an embodiment, the process 880 may continue with operation 883, which comprises curing the liquid adhesive to maintain the profile. In an embodiment, the curing process may include a UV cure, a thermal cure, or the like. In an embodiment, the curing process may be implemented substantially right after the scraping process. For example, a UV light source may be coupled to a backend of the scraping tool in order to cure the liquid adhesive at substantially the same time the liquid adhesive is set to a desired profile. This may prevent the profile from significantly deforming after the scraping process.

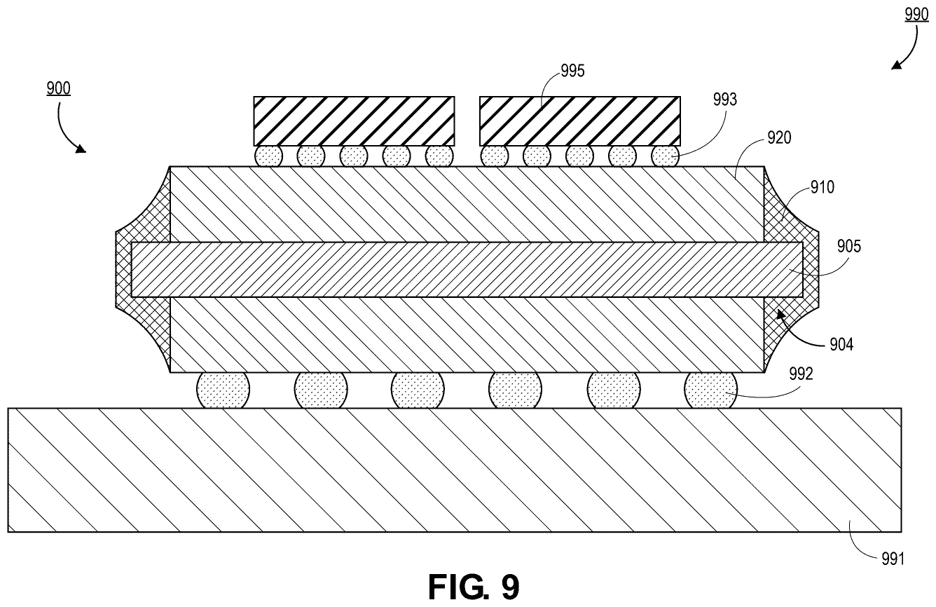

Referring now to FIG. 9, a cross-sectional illustration of an electronic system 990 is shown, in accordance with an embodiment. In an embodiment, the electronic system 990 may comprise a board 991, such as a printed circuit board (PCB), a motherboard, or the like. In an embodiment, the board 991 may be electrically coupled to a package substrate 900 by interconnects 992. The interconnects 992 may comprise solder balls, sockets, pins, or any other suitable second level interconnect (SLI) architecture.

In an embodiment, the package substrate 900 may be similar to any of the package substrates described in greater detail herein. For example, the package substrate 900 may comprise a glass core substrate 905 between buildup layers 920. In an embodiment, a portion 904 of the glass core substrate 905 may extend beyond an edge of the buildup layers 920. In order to provide additional protection to the exposed portion 904, a buffer layer 910 may be provided over the glass core substrate 905. The buffer layer 910 may be similar to any of the buffer layers described herein. For example, the buffer layer 910 may have a controlled profile in order to allow for easier handling and/or identification with optical systems. The buffer layer 910 may be applied with a roller coating process, or the like. For example, any of the roller coating processes, roller coating tools, and/or scraping tools described herein may be used to form the buffer layer 910.

In an embodiment, one or more dies 995 may be electrically coupled to the package substrate 900 through interconnects 993. In an embodiment, the interconnects may comprise solder balls, copper bumps, hybrid bonding interfaces, or any other suitable FLI architecture. In an embodiment, the one or more dies 995 may comprise any type of die, such as processor (e.g., a central processing unit (CPU), a graphics processing unit (GPU), an XPU, etc.), a memory die, a communications die, and/or the like. In some embodiments, a bridge (not shown) is embedded in the buildup layer 920 or provided over the buildup layer 920. The bridge may electrically couple two dies 995 together. That is, an electrically conductive path may be provided from a first die 995 to a second die 995, and the electrically conductive path may pass through and/or over the bridge.

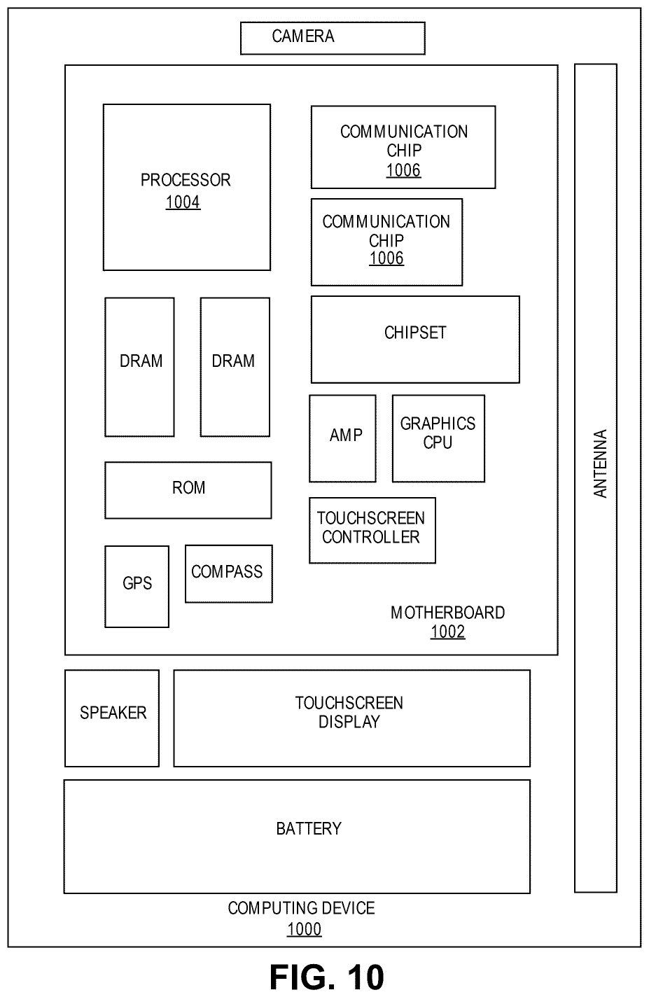

FIG. 10 illustrates a computing device 1000 in accordance with one implementation of the disclosure. The computing device 1000 houses a board 1002. The board 1002 may include a number of components, including but not limited to a processor 1004 and at least one communication chip 1006. The processor 1004 is physically and electrically coupled to the board 1002. In some implementations the at least one communication chip 1006 is also physically and electrically coupled to the board 1002. In further implementations, the communication chip 1006 is part of the processor 1004.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 1006 enables wireless communications for the transfer of data to and from the computing device 1000. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1006 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond.

The computing device 1000 may include a plurality of communication chips 1006. For instance, a first communication chip 1006 may be dedicated to shorter range wireless communications such as Wi-Fi and Bluetooth and a second communication chip 1006 may be dedicated to longer range wireless communications such as GPS, EDGE, GPRS, CDMA, WiMAX, LTE, Ev-DO, and others.

The processor 1004 of the computing device 1000 includes an integrated circuit die packaged within the processor 1004. In some implementations of the disclosure, the integrated circuit die of the processor may be part of an electronic package that comprises a glass core and a buffer layer protecting an edge of the glass core, in accordance with embodiments described herein. The term “processor” may refer to any device or portion of a device that processes electronic data from registers and/or memory to transform that electronic data into other electronic data that may be stored in registers and/or memory.

The communication chip 1006 also includes an integrated circuit die packaged within the communication chip 1006. In accordance with another implementation of the disclosure, the integrated circuit die of the communication chip may be part of an electronic package that comprises a glass core and a buffer layer protecting an edge of the glass core, in accordance with embodiments described herein.

In an embodiment, the computing device 1000 may be part of any apparatus. For example, the computing device may be part of a personal computer, a server, a mobile device, a tablet, an automobile, or the like. That is, the computing device 1000 is not limited to being used for any particular type of system, and the computing device 1000 may be included in any apparatus that may benefit from computing functionality.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

Example 1: an apparatus, comprising: a first substrate, wherein the first substrate comprises a glass layer; a second substrate over the first substrate, wherein the second substrate comprises an organic buildup layer, wherein a first width of the first substrate is greater than a second width of the second substrate; and wherein an edge between a first corner of the first substrate and a second corner of the first substrate comprises a curve.

Example 2: the apparatus of Example 1, wherein the curve is concave.

Example 3: the apparatus of Example 1 or Example 2, wherein the second substrate comprises buildup layers with electrically conductive routing embedded within the second substrate.

Example 4: the apparatus of Examples 1-3, wherein the first corner and the second corner are rounded corners.

Example 5: the apparatus of Examples 1-4, wherein the first substrate comprises a second edge between a third corner and a fourth corner, and wherein the second edge comprises a second curve.

Example 6: the apparatus of Example 5, wherein the second curve is a mirror image of the curve.

Example 7: the apparatus of Example 5 or Example 6, wherein a third edge between the first corner and the third corner comprises a third curve, and wherein a fourth edge between the second corner and the fourth corner comprises a fourth curve.

Example 8: the apparatus of Examples 1-7, wherein the edge comprises a plurality of curves.

Example 9: the apparatus of Examples 1-8, further comprising a layer around a perimeter of the first substrate, and wherein an outer edge of the layer is substantially linear.

Example 10: the apparatus of Examples 1-9, wherein the first corner and the second corner comprise circular protrusions.

Example 11: an apparatus, comprising: a package substrate, wherein the package substrate comprises a glass core and a buildup layer over and under the glass core, and wherein the glass core comprises an outer edge with a concave curve; and a layer around a perimeter of the package substrate, wherein the layer comprises a dielectric material, and wherein the layer directly contacts the glass core.

Example 12: the apparatus of Example 11, wherein the glass core comprises a plurality of outer edges, and wherein each of the plurality of outer edges comprises a concave curve.

Example 13: the apparatus of Example 11 or Example 12, wherein the outer edge comprises a linear portion and the concave curve.

Example 14: the apparatus of Examples 11-13, wherein a corner of the glass core is rounded.

Example 15: the apparatus of Examples 11-14, wherein a corner of the glass core comprises a circular protrusion.

Example 16: the apparatus of Examples 11-15, wherein the layer has an outer perimeter that comprises a substantially rectangular shape.

Example 17: an apparatus, comprising: a substrate with a core, wherein the core comprises a glass layer, and wherein the core has a first perimeter that comprises a curved edge; and a layer surrounding the substrate, wherein the layer comprises a dielectric material, and wherein the layer has a second perimeter where all edges along the second perimeter are substantially linear.

Example 18: the apparatus of Example 17, wherein the core is symmetric about a line that passes through a center of the core.

Example 19: the apparatus of Example 17 or Example 18, wherein the layer directly contacts the core.

Example 20: the apparatus of Examples 17-19, wherein the layer comprises a material that is cured with an ultraviolet radiation exposure.

What is claimed is:

1. An apparatus, comprising:
a first substrate, wherein the first substrate comprises a glass layer;
a second substrate over the first substrate, wherein the second substrate comprises an organic buildup layer, wherein a first width of the first substrate is greater than a second width of the second substrate; and
wherein an edge between a first corner of the first substrate and a second corner of the first substrate comprises a curve.

2. The apparatus of claim 1, wherein the curve is concave.

3. The apparatus of claim 1, wherein the second substrate comprises buildup layers with electrically conductive routing embedded within the second substrate.

4. The apparatus of claim 1, wherein the first corner and the second corner are rounded corners.

5. The apparatus of claim 1, wherein the first substrate comprises a second edge between a third corner and a fourth corner, and wherein the second edge comprises a second curve.

6. The apparatus of claim 5, wherein the second curve is a mirror image of the curve.

7. The apparatus of claim 5, wherein a third edge between the first corner and the third corner comprises a third curve, and wherein a fourth edge between the second corner and the fourth corner comprises a fourth curve.

8. The apparatus of claim 1, wherein the edge comprises a plurality of curves.

9. The apparatus of claim 1, further comprising a layer around a perimeter of the first substrate, and wherein an outer edge of the layer is substantially linear.

10. The apparatus of claim 1, wherein the first corner and the second corner comprise circular protrusions.

11. An apparatus, comprising:
a package substrate, wherein the package substrate comprises a glass core and a buildup layer over and under the glass core, and wherein the glass core comprises an outer edge with a concave curve; and
a layer around a perimeter of the package substrate, wherein the layer comprises a dielectric material, and wherein the layer directly contacts the glass core.

12. The apparatus of claim 11, wherein the glass core comprises a plurality of outer edges, and wherein each of the plurality of outer edges comprises a concave curve.

13. The apparatus of claim 11, wherein the outer edge comprises a linear portion and the concave curve.

14. The apparatus of claim 11, wherein a corner of the glass core is rounded.

15. The apparatus of claim 11, wherein a corner of the glass core comprises a circular protrusion.

16. The apparatus of claim 11, wherein the layer has an outer perimeter that comprises a substantially rectangular shape.

17. An apparatus, comprising:
a substrate with a core, wherein the core comprises a glass layer, and wherein the core has a first perimeter that comprises a curved edge; and
a layer surrounding the substrate, wherein the layer comprises a dielectric material, and wherein the layer has a second perimeter where all edges along the second perimeter are substantially linear.

18. The apparatus of claim 17, wherein the core is symmetric about a line that passes through a center of the core.

19. The apparatus of claim 17, wherein the layer directly contacts the core.

20. The apparatus of claim 17, wherein the layer comprises a material that is cured with an ultraviolet radiation exposure.
